(19) United States
(12) Patent Application Publication
(10) Pub. No.: US 2008/0169704 A1
(43) Pub. Date: Jul. 17, 2008

(54) ADVANCED MOBILE POWER SYSTEM

(75) Inventors: Ralph Ferraro, Knoxville, TN (US); Cheng-Guan Michael Quah, Farmington Hills, MI (US); Paul Stanley Makar, Lake Orlon, MI (US); James Patrick Muldoon, Avoca, MI (US)

Correspondence Address: YOUNG & BASILE, P.C., 3001 WEST BIG BEAVER ROAD, SUITE 624, TROY, MI, 48084, US

(73) Assignee: COFFMAN ELECTRICAL EQUIPMENT CO., Grand Rapids, MI (US)

(21) Appl. No.: 11/853,413

(22) Filed: Sep. 11, 2007

Related U.S. Application Data
(60) Provisional application No. 60/843,632, filed on Sep. 11, 2006.

(51) Int. Cl. H02J 9/00; H05K 7/00

(52) U.S. Cl. 307/64; 361/728

(57) ABSTRACT

An advanced mobile micro grid power system is disclosed. The system 10 can be adaptable for use in military and other applications. The system includes one or more rugged modules to convert input power from heterogeneous sources such as vehicles, field generators and other sources, into high quality power output such as might serve a military encampment. Each module can be capable of operation in grid-parallel mode or in an island mode. The modules are able to start without utility grid power present.

### CROSS-REFERENCE TO RELATED APPLICATIONS

This application claims priority from U.S. Provisional Patent Application Ser. No. 60/843,632 filed Sep. 11, 2006, the disclosure of which is hereby incorporated by reference in its entirety.

### TECHNICAL FIELD

The present invention generally relates to mobile power supply systems and more particularly to mobile power supply systems for micro grids.

### BACKGROUND

A need exists for electric power in remote environments such as military battlefields that may not have access to reliable, highly conditioned electric power of a desired voltage, amperage and frequency.

U.S. Pat. No. 6,603,672 (the disclosure of which is hereby incorporated by reference in its entirety) discloses a power converter system that allows various types of power signals to be received and converted in a predetermined manner to supplement power for a grid. U.S. Pat. No. 5,804,953 (the disclosure of which is hereby incorporated by reference in its entirety) discloses a power converter for converting AC shore power to shipboard use, which converts a variety of shore voltages for shipboard use. U.S. Patent Application No. 2005/0105306 (the disclosure of which is hereby incorporated by reference in its entirety) discloses a power converter that is adaptable for interfacing a variety of power sources with a three-phase AC power grid. U.S. Patent Application No. 2004/0124711 (the disclosure of which is hereby incorporated by reference in its entirety) discloses a mobile power system in a standard freight container; the system distributes power in a plurality of configurations such as different voltage. U.S. Patent Application No. 2004/0061380 (the disclosure of which is hereby incorporated by reference in its entirety) discloses a power management system for variable load applications. U.S. Patent Application No. 2002/0036430 (the disclosure of which is hereby incorporated by reference in its entirety) discloses a local area grid for distributed power.

### SUMMARY

A mobile power supply is provided having: a housing of a size and configuration suitable for transit as cargo aboard ships, aircraft or large vehicles; a plurality of removable input ports mounted to the housing and adapted to accept AC and DC power from a range of heterogeneous power sources; a plurality of PC&C units each coupled to two or more of the plurality of removable input ports; a controller coupled to the PC&C units and removable units to selectively enable at least one of the units and one of the removable input ports; and at least one surge control circuit coupled to at least one of the removable input ports; the surge control circuit configured to transform incoming power to a predetermined level of direct current voltage.

### BRIEF DESCRIPTION OF THE DRAWINGS

The description herein makes reference to the accompanying drawings wherein like reference numerals refer to like parts throughout the several views, and wherein:

FIG. 1 is a front perspective depictional view of an example of a mobile power system in accordance with the invention (with the roof panel removed to illustrate the interior components);

FIG. 2 is a rear perspective depictional view of the power system of FIG. 1;

FIG. 3 is a block diagram of a first example of the invention; and

FIG. 4 is a block diagram of a second example of the invention.

### DETAILED DESCRIPTION

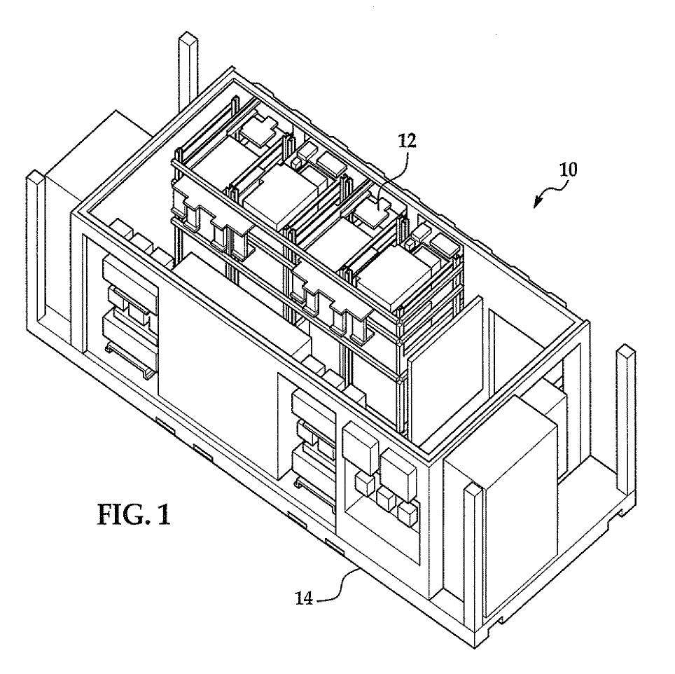

Introduction. Referring to FIGS. 1-4, an advanced mobile microgrid power system 10 is shown. System 10 can be adaptable for use in military and other applications. System 10 includes a one or more rugged modules 12 to convert input power from heterogeneous sources such as vehicles, field generators and other sources, into high quality power output such as might serve a military encampment. Each module 12 can be capable of operation in grid-parallel mode or in an island mode. The modules are able to start without utility grid power present.

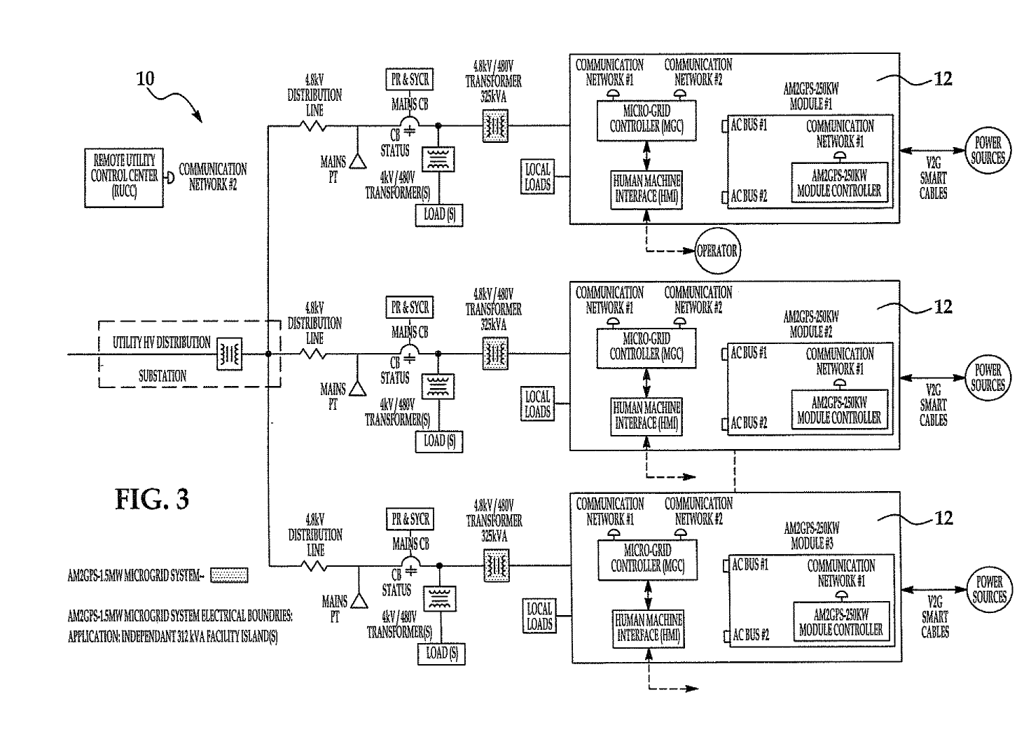

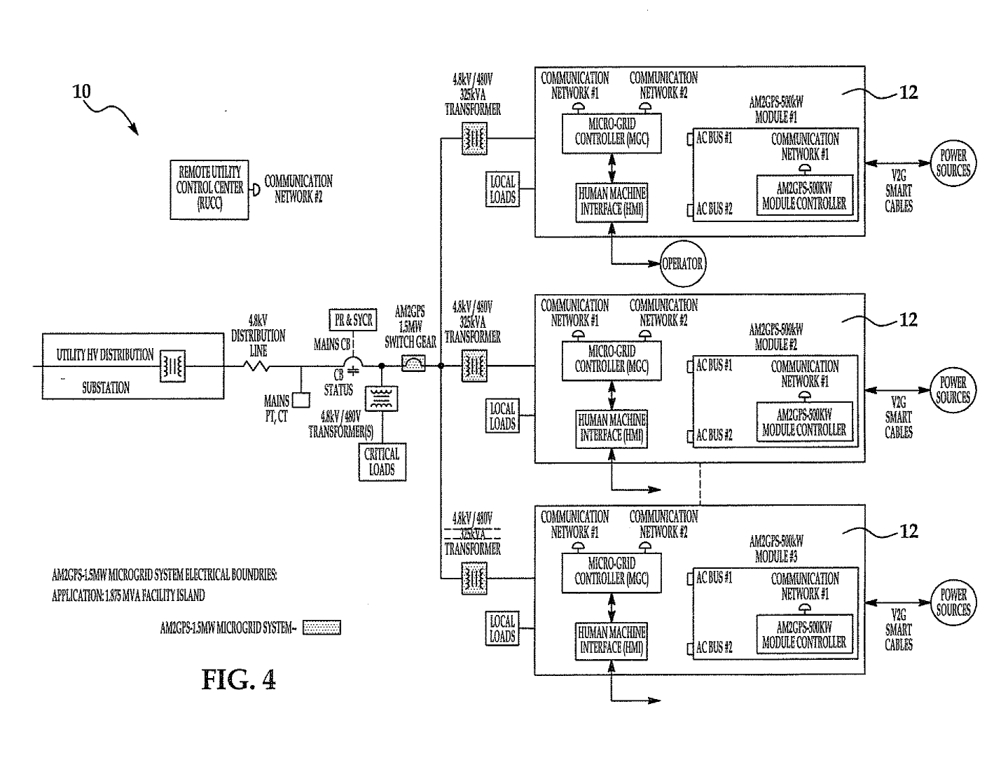

Universal Power Conditioning. As shown in FIGS. 3 and 4, the modules 12 include two PC&C units, with each unit providing four input ports to accept AC and DC power sources at the same time. Input ports can accommodate a range of power types. While it is known to convert and condition power from a specific target source, the module 12 can accept as input a range of heterogeneous and dirty power sources. Each module 12 can be configured to meet each particular environment of input power. The modules 12 can receive power input from multiple sources at the same time and use this input to create a single, clean output signal.

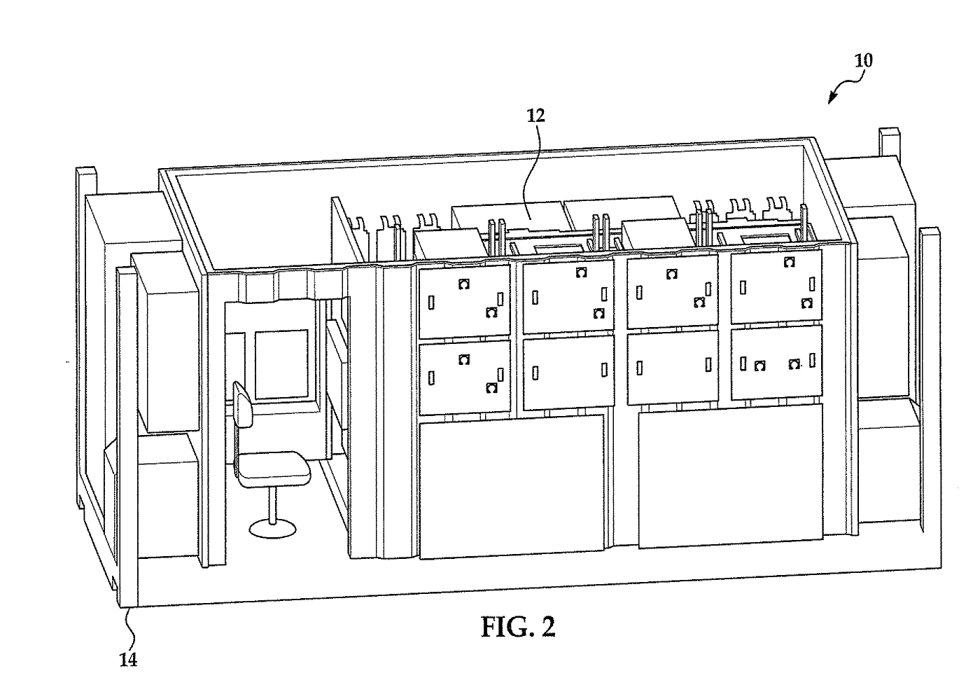

Removable Ports. As shown in FIG. 2, to permit reconfiguration in inputs, the ports to the modules 12 are removable. Each port can be adapted for a specific class of input, so by interchanging ports, the module 12 can be quickly configured for the available power sources.

Control Algorithms. To permit the conversion of a wide variety of input power sources to a predetermined configuration of outputs, power input can be converted to 650 volts DC using control algorithms. The modules 12 are adapted to communicate with each other, with the grid and with the sources of power. When the modules 12 are deployed in the field, one acts as the master and the remainder act as slaves. If the master unit became disabled, a slave can immediately assume the role of master. Modules 12 can also be interconnected in terms of power and can be ganged together or operate in parallel.

Packaging. While power conversion units are known, modules 12 can be robustly packaged for deployment in field as a single unit. As shown in FIGS. 1 and 2, a housing 14 includes mechanisms for shock protection, and the specific configuration of components used in the housing. Housing 14 can be a portable unit such as a standardized cargo container.

Surge Management. To achieve conversion, each module 12 transforms incoming power to 650 volts DC before converting the DC to the desired output. A DC surge control provides stability if input power surges. An AC surge control allows the modules 12 to meet momentary surges in load amperage. By managing these surges, the module 12 avoids the necessity for having excess input capacity, reducing fuel requirements.

Physical Connectors. Unique physical and logical connections are established between inputs and outputs using unique connectors that permit both data and power lines as shown in FIGS. 2-4.

The above-described embodiments have been described in order to allow easy understanding of the invention and do not limit the invention. On the contrary, the invention is intended to cover various modifications and equivalent arrangements included within the scope of the appended claims, which scope is to be accorded the broadest interpretation so as to encompass all such modifications and equivalent structure as is permitted under the law.

What is claimed is:

1. A mobile power supply comprising:
a housing of a size and configuration suitable for transit as cargo aboard ships, aircraft or vehicles;
a plurality of removable input ports mounted to the housing and adapted to accept AC and DC power from a range of heterogeneous power sources;
a plurality of PC&C units each coupled to two or more of the plurality of removable input ports;
a controller coupled to the PC&C and removable units to selectively enable at least one of the units and one of the removable input ports; and
at least one surge control circuit coupled to at least one of the removable input ports, the surge control circuit configured to transform incoming power to a predetermined level of direct current voltage.
